(19) United States
(12) Patent Application Publication
(10) Pub. No.: US 2026/0274324 A1
(43) Pub. Date: Sep. 17, 2026

(54) ADVANCED HAPTIC AND SENSING STEERING WHEEL SWITCH

(71) Applicant: Tesla, Inc., Austin, TX (US)

(72) Inventors: Amir Bigdeli, Fremont, CA (US); Bharath Swaminathan, Livermore, CA (US); Cameron Rosen, Fremont, CA (US); Matthew Tran, Austin, TX (US)

(21) Appl. No.: 19/474,971

(22) PCT Filed: Apr. 11, 2024
(86) PCT No.: PCT/US2024/024118

§ 371 Date: Oct. 13, 2025

Related U.S. Application Data
(60) Provisional application No. 63/495,859, filed on Apr. 13, 2023.

(51) Int. Cl. B62D 1/04; G06F 3/01; G06F 3/0362; G06F 3/038; G06F 3/044

(52) U.S. Cl. CPC B62D 1/046; G06F 3/016; G06F 3/0362; G06F 3/038; G06F 3/044; G06F 2203/04108

(57) ABSTRACT

A device may include a piezoelectric actuator and a processor. The piezoelectric actuator is configured to: generate a first electric signal in response to a first user contact associated with the switchpack; and generate a haptic feedback based on a control signal. The processor is configured to: determine, based at least in part on the first electric signal, that the first user contact indicates a first user operation; and generate the control signal based on the first user operation.

### CROSS-REFERENCE TO RELATED APPLICATIONS

This application claims the benefit of U.S. Provisional Application No. 63/495,859, filed Apr. 13, 2023, the entire disclosure of which is hereby incorporated by reference in its entirety.

### TECHNICAL FIELD

The present disclosure relates to a system and method for sensing and providing haptic feedback. More particularly, the present disclosure relates to a steering wheel switch for sensing user input and providing haptic feedback.

### BACKGROUND

Steering wheel assemblies are associated with a number of automotive applications to allow a driver to maneuver a vehicle. Current steering wheel assemblies are primarily used to control a movement of the vehicle. However, there are many other functionalities that the driver may need to change or update while driving, for example selecting driver-assist functionality, activating turn signals, activating a horn, controlling the climate (for example increasing or decreasing the cabin temperature or increasing or decreasing the fan speed), making a telephone call, or another action.

Some steering wheel assemblies include one or more force sensitive components disposed in a steering wheel switch. The force sensitive component generates electric signals in response to force applied on the steering wheel switch. The steering wheel switch may further integrate a haptic device to provide haptic feedback. However, extra cost may be incurred to integrate separate devices to implement both force sensing and haptic feedback functionalities. Additionally, performing these functionalities reliably are also of great importance but can be quite challenging under limited hardware resources.

### SUMMARY

An aspect is directed to a switchpack for a vehicle. The switchpack comprises a sensor adapted to generate an electric signal in response to a force applied on the sensor by a user and provide haptic feedback to the user in response to the force applied on the sensor.

In some aspects, the techniques described herein relate to a switchpack for a vehicle, including: a piezoelectric actuator configured to: generate a first electric signal in response to a first user contact associated with the switchpack; and generate a haptic feedback based on a control signal; and a processor configured to: determine, based at least in part on the first electric signal, that the first user contact indicates a first user operation; and generate the control signal based on the first user operation.

In some aspects, the techniques described herein relate to a switchpack, further including: a first button; and a capacitive foil configured to generate a second electric signal in response to the first user contact, wherein the processor determines that the first user contact indicates the first user operation further based on the second electric signal.

In some aspects, the techniques described herein relate to a switchpack, wherein the first user operation is a user pressing the first button, or the user touching the first button without pressing the first button.

In some aspects, the techniques described herein relate to a switchpack, further including: a second button, wherein a first ratio between a first distance from a center of the first button to a center of the piezoelectric actuator and a second distance from the center of the piezoelectric actuator to an edge of the switchpack equals a second ratio between a third distance from a center of the second button to the center of the piezoelectric actuator and a fourth distance from the center of the piezoelectric actuator to the edge of the switchpack.

In some aspects, the techniques described herein relate to a switchpack, further including: a scroll wheel; and a first 3D Hall effect sensor configured to generate a first sensing signal in response to a second user contact on the scroll wheel, wherein the processor is further configured to determine, based at least in part on the first sensing signal, that the second user contact indicates a second user operation.

In some aspects, the techniques described herein relate to a switchpack, wherein the second user operation is a press on the scroll wheel, a tilt to a right on the scroll wheel, or a tilt to a left on the scroll wheel.

In some aspects, the techniques described herein relate to a switchpack, further including: a mechanical microswitch configured to generate a second sensing signal in response to the second user contact, wherein the processor determines that the second user contact indicates the second user operation further based on the second sensing signal.

In some aspects, the techniques described herein relate to a switchpack, further including: a second 3D Hall effect sensor configured to generate a third sensing signal in response to the second user contact, wherein the processor determines that the second user contact indicates the second user operation further based on the third sensing signal.

In some aspects, the techniques described herein relate to a switchpack, wherein determining that the second user contact indicates the second user operation includes: summing the first sensing signal and the third sensing signal along a x-axis; summing the first sensing signal and the third sensing signal along a y-axis; or summing the first sensing signal and the third sensing signal along a z-axis.

In some aspects, the techniques described herein relate to a switchpack, further including: a magnet at least partially surrounded by the scroll wheel, wherein the first 3D Hall effect sensor and the second 3D Hall effect sensor are equally distant from a magnetization line of the magnet.

In some aspects, the techniques described herein relate to a switchpack, wherein the scroll wheel includes a first scroll tick and a second scroll tick, and wherein the first scroll tick and the second scroll tick have about a 15-degree offset against the magnetization line of the magnet.

In some aspects, the techniques described herein relate to a steering wheel for a vehicle, including: a steering wheel switch, including: a sensor configured to: generate a first electric signal in response to a first user contact associated with the steering wheel switch; and generate a haptic feedback based on a control signal; and a processor configured to: determine, based at least in part on the first electric signal, that the first user contact indicates a first user operation; and generate the control signal based on the first user operation.

In some aspects, the techniques described herein relate to a steering wheel, further including: a button, and a capacitive foil configured to generate a second electric signal in response to the first user contact, wherein the processor determines that the first user contact indicates the first user operation further based on the second electric signal.

In some aspects, the techniques described herein relate to a steering wheel, further including: a scroll wheel; and a first 3D Hall effect sensor configured to generate a first sensing signal in response to a second user contact on the scroll wheel, wherein the processor is further configured to determine, based at least in part on the first sensing signal, that the second user contact indicates a second user operation.

In some aspects, the techniques described herein relate to a steering wheel, further including: a mechanical microswitch configured to generate a second sensing signal in response to the second user contact,

In some aspects, the techniques described herein relate to wherein the processor determines that the second user contact indicates the second user operation further based on the second sensing signal.

In some aspects, the techniques described herein relate to a steering wheel, further including: a second 3D Hall effect sensor configured to generate a third sensing signal in response to the second user contact, wherein the processor determines that the second user contact indicates the second user operation further based on the third sensing signal.

In some aspects, the techniques described herein relate to a method for calibrating a steering wheel switch of a vehicle, the method including: setting a scroll wheel to a first discrete angular position; pressing the scroll wheel to change the scroll wheel from an unpressed state to a pressed state; and determining a first 3D magnetic field difference associated with the unpressed state and the pressed state at the first discrete angular position.

In some aspects, the techniques described herein relate to a method, further including: sensing a first 3D magnetic field associated with the unpressed state at the first discrete angular position; and sensing a second 3D magnetic field associated with the pressed state at the first discrete angular position, wherein determining the first 3D magnetic field difference is based on the first 3D magnetic field and the second 3D magnetic field.

In some aspects, the techniques described herein relate to a method, further including: recording the first 3D magnetic field difference; setting the scroll wheel to a second discrete angular position; pressing the scroll wheel to change the scroll wheel from the unpressed state to the pressed state; determining a second 3D magnetic field difference associated with the unpressed state and the pressed state at the second discrete angular position; and recording the second 3D magnetic field difference.

In some aspects, the techniques described herein relate to a method, further including: generating a sensing signal in response to a first user contact on the scroll wheel; and determining, based at least in part on the sensing signal and the first 3D magnetic field difference, that the first user contact indicates a first user operation, wherein the first user operation is a press on the scroll wheel, a tilt to a right on the scroll wheel, or a tilt to a left on the scroll wheel.

### BRIEF DESCRIPTION OF THE DRAWINGS

Embodiments of the present disclosure are described with reference to the accompanying drawings, in which like reference characters reference like elements, and wherein:

FIG. 1 illustrates an example steering wheel switch according to some embodiments of the present disclosure.

FIG. 2 is a diagram illustrating components of a steering wheel switch that are utilized to provide sensing and haptic functionalities in accordance with some embodiments of the present disclosure.

FIG. 3 illustrates an example internal view of the steering wheel switch illustrated in FIG. 1.

FIG. 4 illustrates example waveforms of voltages generated by force sensing devices, such as the piezoelectric actuator and the capacitive foil of FIG. 2.

FIG. 5 depicts an example waveform associated with a haptic device such as the piezoelectric actuator of FIG. 2 and the piezoelectric actuator of FIG. 3.

FIGS. 6A-6C illustrate example waveforms that can be generated by using different algorithms (e.g., summation or subtraction of outputs along a single x, y or z axis) to process outputs of Hall effect sensors (e.g., Hall effect sensors) under different manipulations of a scroll wheel (e.g., scroll wheel) by a user.

FIG. 7 illustrates an example routine for calibrating a scroll wheel of a steering wheel switch, such as the steering wheel switch of FIG. 1, in accordance with some embodiments of the present disclosure.

FIG. 8 illustrates an example integration of a magnet, a scroll wheel (e.g., the scroll wheel) and two 3D Hall effect sensors (e.g., the 3D Hall effect sensors).

FIG. 9 illustrates an example block diagram showing different components that can be packed within a steering wheel switch, such as the steering wheel switch of FIG. 1.

### DETAILED DESCRIPTION

Generally described, one or more aspects of the present disclosure correspond to systems and methods that use a single component to provide both force sensing and haptic feedback functionalities. Additionally, the disclosed systems and methods further implement techniques that utilize signal redundancy in sensing an input to achieve reliability in the aforementioned functionalities. Illustratively, some aspects of the present disclosure relate to a steering wheel switch that utilizes a piezoelectric actuator to both sense forces applied (e.g., by a user finger) and provide customized haptic feedback. Additionally, the steering wheel switch may be further integrated with one or more capacitive foils for location sensing. In some embodiments, the steering wheel switch may further include one or more Hall effect sensors to detect various types of user contact, such as press, scroll, and tilt in different directions or sides. In some embodiments, the combinations of sensing outputs provided by the piezoelectric actuator, capacitive foils, and Hall effect sensors achieve system redundancy that results in more reliable sensing and haptic feedback functionalities.

In traditional designs, steering wheel assemblies typically employ separate hardware for providing sensing and haptic feedback functionalities. For example, a steering wheel switch (an integrated portion of a steering wheel assembly) may employ a sensor (e.g., an optical sensor or an infrared (IR) sensor) to sense forces applied by a user and a separate component for providing haptic feedback to the user. The separate component for providing haptic feedback may take the form of a coil that may be heavy or occupy additional spaces. Such approaches can also lead to challenges in layout and signal routing as more components have to be packaged and integrated together.

Additionally, the reliability in sensing user inputs and providing haptic feedback is critical to ensure functional safety. Some systems employ force calibration to normalize the quality of haptic feedback to ensure superior user experience and safety. Other systems employ different kinds of sensing techniques to improve the accuracy of sensing and haptic feedback. Still, these techniques may not always yield satisfactory results due to the limited accuracy of sensors and the potential inadequacy of the calibration processes.

To address at least a portion of the above problems, a steering wheel switch or a switchpack thereof is disclosed in accordance with some embodiments of the present disclosure. In some embodiments, the steering wheel switch can support both force sensing and haptic feedback functionalities without increasing the cost and complexity of integration. For example, the steering wheel switch may include a single piezoelectric actuator that senses forces applied to one or more buttons of the steering wheel switch. In response to the force applied, the piezoelectric actuator may then provide haptic feedback to the user. In some embodiments, the haptic feedback can be customized by the user to achieve different haptics (e.g., buzzy, weak, strong, or clicky), thereby accomplishing different or superior user experience. In other embodiments, there can be more than one piezoelectric actuator or other haptic devices integrated within the steering wheel switch. Yet, advantageously, utilizing one piezoelectric actuator for providing both force sensing and haptic feedback can result in cost reduction and lead to easier hardware integration.

In some embodiments, in addition to the piezoelectric actuator, the steering wheel switch may further employ another mechanism for sensing user input. For example, one or more capacitive foils (or capacitive films) may be deployed on a surface of the steering wheel switch to detect user finger placement for location sensing. In some examples, the outputs generated by the piezoelectric actuator and a capacitive foil can be correlated and may be considered to result in “redundancy” to some degree. Such redundancy, however, can be utilized to validate outputs generated by the piezoelectric actuator and the capacitive foils. As such, the associated sensing and haptic can be conducted more reliably.

In some embodiments, the steering wheel switch may include a scroll wheel that is paired with one or more Hall effect sensors to sense different user contacts, including but not limited to, press, scroll or tilt along different directions or sides. For example, the steering wheel switch may include the scroll wheel and two three-dimensional (3D) Hall effect sensors to detect contacts (e.g., press, tilt to the right, and tilt to the left) of a user on the scroll wheel. In some embodiments, the steering wheel switch may further include one or more mechanical microswitches for sensing user contacts. For example, the steering wheel switch may include two 3D Hall effect sensors and three mechanical microswitches to sense press, tilt to the right and tilt to the left on the scroll wheel. Specifically, the two 3D Hall effect sensors can sense the press, tilt to the right and tilt to the left, and each of the three mechanical microswitches can sense one of the press, tilt to the right, and tilt to the left. As such, the outputs generated by the two 3D Hall effect sensors and the three microswitches can provide redundancy for validating each other, thereby resulting in better functional reliability.

Although the various aspects will be described in accordance with illustrative embodiments and combination of features, one skilled in the relevant art will appreciate that the examples and combination of features are illustrative in nature and should not be construed as limiting. More specifically, aspects of the present application may be applicable with various types of steering wheel assemblies, steering wheel switches, switchpacks, interfaces and the like. Still further, although a specific architecture of steering wheel switch for providing force sensing, location sensing and haptic feedback will be described, such illustrative steering wheel switch design or architecture should not be construed as limiting. Accordingly, one skilled in the relevant art will appreciate that the aspects of the present application are not necessarily limited to application to any particular type of steering wheel assemblies, steering wheel infrastructure or illustrative interactions between users/drivers and steering wheels of vehicles.

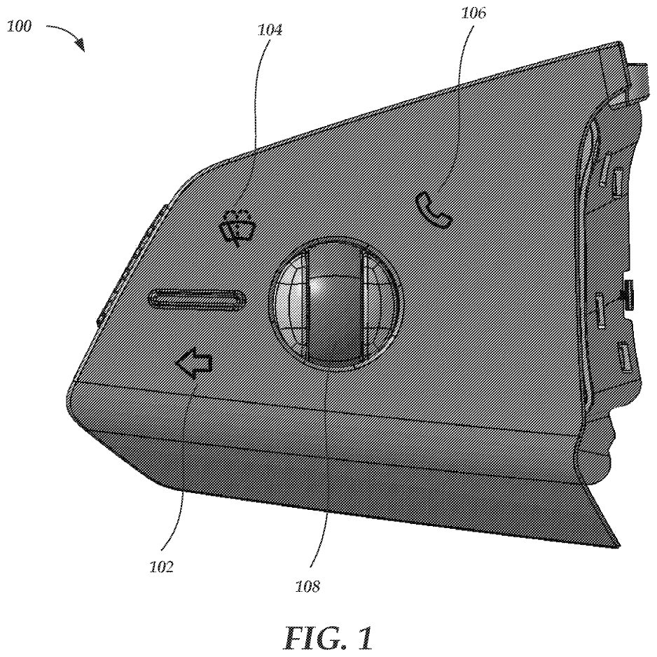

FIG. 1 illustrates an example steering wheel switch 100 according to some embodiments of the present disclosure. As shown in FIG. 1, the steering wheel switch 100 is standalone. However, the steering wheel switch 100 may also be installed to a steering wheel (not shown in FIG. 1) and integrated as a part of the steering wheel of vehicles. Examples of vehicles may include automobiles, vans, trucks, maritime vessels, aircraft, or spacecraft. As illustrated in FIG. 1, the steering wheel switch 100 may include a scroll wheel 108, button 102, button 104 and button 106 on its surface. As also illustrated in FIG. 1, the steering wheel switch 100 may further include connections on different sides that allow the steering wheel switch 100 to be mechanically connected to other parts (not shown in FIG. 1) of a steering wheel of a vehicle. In some embodiments, the steering wheel switch 100 may house various sensors and components (not shown in FIG. 1) for sensing forces applied on certain surfaces (e.g., the surface of the scroll wheel 108) of the steering wheel switch 100 to provide haptic feedback in response to the sensed forces.

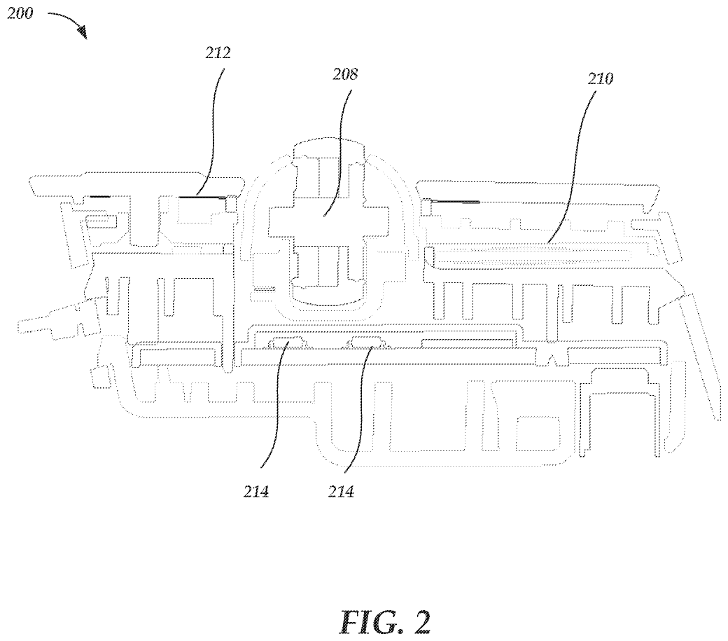

FIG. 2 is a diagram illustrating components of a steering wheel switch 200 that are utilized to provide sensing and haptic functionalities in accordance with some embodiments of the present disclosure. The steering wheel switch 200 illustrated in FIG. 2 can be the same as the steering wheel switch 100 of FIG. 1. The components of a steering wheel switch 200 illustrated in FIG. 2 include a piezoelectric actuator 210, a capacitive foil 212, two 3D Hall effect sensors 214 and a scroll wheel 208. In some embodiments, the piezoelectric actuator 210 senses forces applied on one or more buttons (not shown in FIG. 2) attached to the surface of the steering wheel switch 200 and converts the sensed forces to electrical signals (e.g., currents or voltages). The electrical signals can be further processed by analog and/or digital circuitry (not shown in FIG. 2) associated with the steering wheel switch 200 to facilitate different operations that a user intends to achieve. In some embodiments, the magnitude of the electrical signals may be correlated to (e.g., proportional) the forces applied on the one or more buttons. Additionally, the piezoelectric actuator 210 can generate haptic feedback, for example, in response to the forces sensed.

In some embodiments, the capacitive foil 212 senses user touch events on the capacitive foil 212 for detecting locations of finger placements of a user. The two 3D Hall effect sensors 214 can sense manipulations of a user on the scroll wheel 208 that correspond to different kinds of user contacts to the scroll wheel 208. In some embodiments, the two 3D Hall effect sensors 214 detect press, tilt to the left and tilt to the right by the user on the scroll wheel 208. Although one piezoelectric actuator 210, one capacitive foil 212, two 3D Hall effect sensors 214 and one scroll wheel 208 are illustrated in FIG. 2, the number of each of the components can be adjusted to result in different combinations of number. For example, instead of having two 3D Hall effect sensors 214, the steering wheel switch 200 can include one 3D Hall effect sensor 214. As another example, there may be more than one capacitive foil 212.

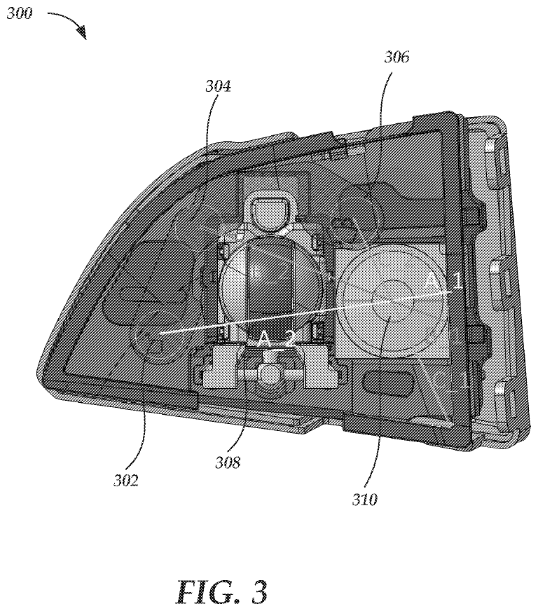

FIG. 3 illustrates an example internal view of a steering wheel switch 300, such as the steering wheel switch 100 illustrated in FIG. 1. As illustrated in FIG. 3, the steering wheel switch 300 includes a button 302, a button 304, a button 306, a scroll wheel 308 and a piezoelectric actuator 310. In operation, when a force is applied on one of the buttons 302, 304 or 306, the piezoelectric actuator 310 may be compressed to a certain extent (e.g., depending on the level or strength of the applied force). In response, the piezoelectric actuator 310 may generate an electrical signal (e.g., a voltage variation in the order of millivolts) that is correlated with the magnitude of the applied force. As such, the generated electrical signal can indicate the strength of force applied on the steering wheel switch 300.

In some embodiments, the button 302, the button 304, the button 306 and/or the piezoelectric actuator 310 are arranged in a configuration such that the distance from the center of each button to the center of the piezoelectric actuator 310 and the corresponding distance from the center of the piezoelectric actuator 310 to the boundary of the steering wheel switch adjacent to the piezoelectric actuator 310 maintain a fixed ratio. More specifically, for the button 302, dividing the distance A_2 (i.e., the distance from the center of button 302 to the center of the piezoelectric actuator 310) by the distance A_1 (i.e., the distance from the center of the piezoelectric actuator 310 extending to the boundary of the steering wheel switch) may be equal to a ratio R. Although not easily observed from FIG. 3, the same ratio R would be derived when the distance B_2 (i.e., the distance from the center of button 304 to the center of the piezoelectric actuator 310) is divided by the distance B_1 (i.e., the distance from the center of the piezoelectric actuator 310 extending to the boundary of the steering wheel switch), and when the distance C_2 (i.e., the distance from the center of button 306 to the center of the piezoelectric actuator 310) is divided by the distance C_1 (i.e., the distance from the center of the piezoelectric actuator 310 extending to the boundary of the steering wheel switch).

The common ratio associated with a button and actuator pair can yield approximately equal compression on the piezoelectric actuator 310 by the button 302, the button 304 and the button 306. Advantageously, such equal compression can increase the accuracy of sensing and may eliminate the need for force sensing calibration among the button 302, the button 304 and the button 306.

In some embodiments, an input force press threshold is implemented to improve user experience. Specifically, a force below the input force press threshold applied on a button may not be sensed by the steering wheel switch 300 or may not cause any haptic feedback. In some examples, the input force press threshold can be adjusted relative to a dynamic baseline that takes various effects (e.g., system stiffness changes due to temperature variation) into consideration. Thus, user experience may be improved.

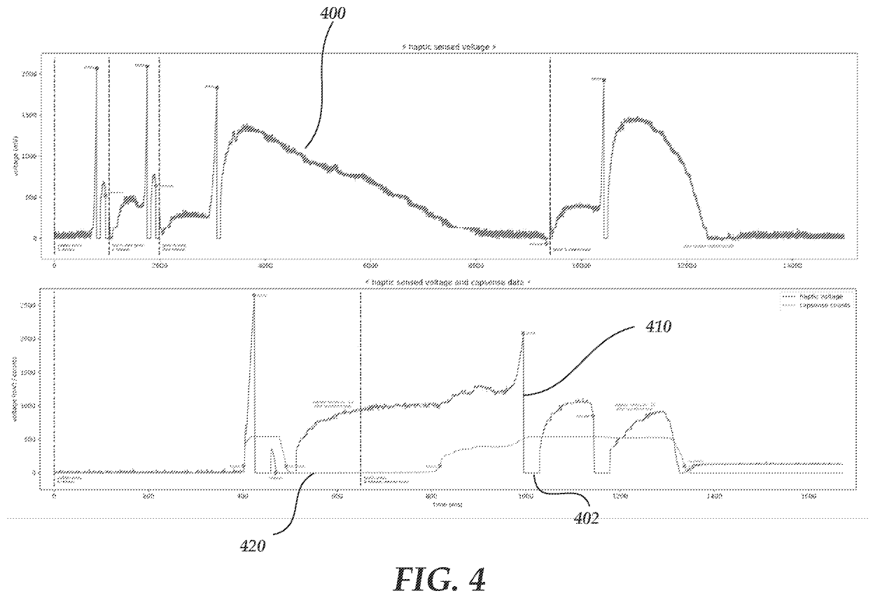

FIG. 4 illustrates example waveforms of voltages generated by force sensing devices, such as the piezoelectric actuator 210 and the capacitive foil 212 of FIG. 2. As shown in the waveform 400 on the top of FIG. 4, the voltage generated by the piezoelectric actuator 210 reaches peak values around the time instants when a user presses on a component (e.g., a button) of the steering wheel switch 200. In contrast, the voltage generated by the piezoelectric actuator 210 dives or gradually goes to near 0 V around the time instants when the user releases or stops from pressing the button. In some examples, the voltage generated by the piezoelectric actuator 210 dives toward 0 V in response to a sudden release of the button or gradually decays toward 0 V in response to a slow release of the button. Advantageously, the rates of different voltage changes may be leveraged to provide more customized haptic profiles.

At the bottom of FIG. 4 shows a voltage waveform 420 generated by the capacitive foil 212 superimposed on a voltage waveform 410 generated by the piezoelectric actuator 210. As shown at the bottom of FIG. 4, some temporal correlation can be observed between the voltage waveforms generated by the capacitive foil 212 and the piezoelectric actuator 210. In some embodiments, the steering wheel switch 200 can utilize this correlation to validate the sensing function performed by the capacitive foil 212 and the piezoelectric actuator 210. As discussed above, this correlation can provide system “redundancy” that can increase the reliability of the force sensing and haptic functions. For example, during the time interval around 402, the voltage waveform 410 generated by the piezoelectric actuator 210 stays around 0 V while the voltage waveform 420 generated by the capacitive foil 212 hovers around peak values. The steering wheel switch 200 may then utilize both waveforms to determine that a user is simply touching a button or a scroll wheel without pressing. Thus, the steering wheel switch 200 may determine that no haptic feedback should be generated, which may be desired or intended by the user.

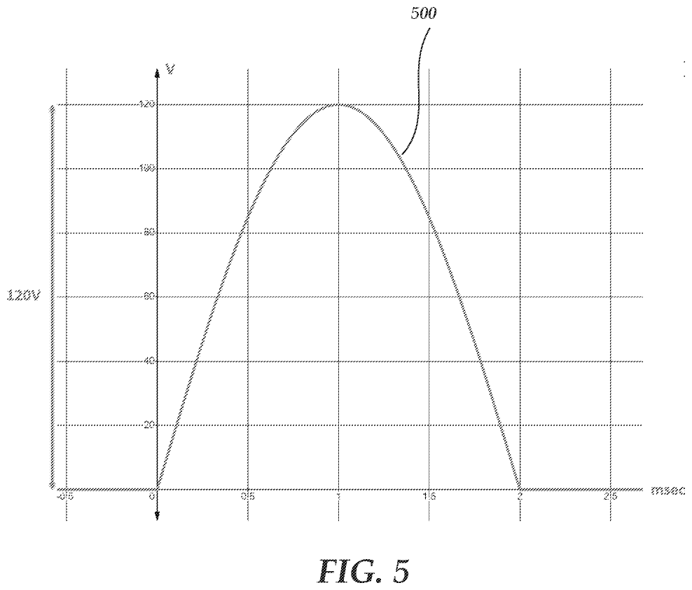

FIG. 5 depicts an example waveform associated with a haptic device such as the piezoelectric actuator 210 of FIG. 2 and the piezoelectric actuator 310 of FIG. 3. As illustrated in FIG. 5, a sinewave-like waveform 500 may be utilized by the piezoelectric actuator 310 to generate certain haptic profile. The sinewave-like waveform 500 illustratively exhibits a frequency of 250 Hz and amplitude of 120 V. In some embodiments, isolation between the steering wheel switch 100 and other components of a steering wheel can be implemented when assembling the steering wheel, thereby achieving a pure resonance frequency of 250 Hz for haptic feedback.

In some embodiments, other types of waveforms having different frequencies and amplitudes can be associated with the piezoelectric actuator 310 to implement different haptic profiles. For example, the amplitude associated with the piezoelectric actuator 310 may exceed 120 V (e.g., 130 V) to realize stronger haptic (e.g., more force felt by the user). As another example, instead of exciting or activating the piezoelectric actuator 310 using the sinewave-like waveform 500 that may give the user a smooth and “clicky” haptic, the piezoelectric actuator 310 may be excited by a triangular waveform to realize “buzzy” haptic. Notably, other frequencies and amplitudes can be associated with the piezoelectric actuator 310 to realize different or more customized haptic profiles.

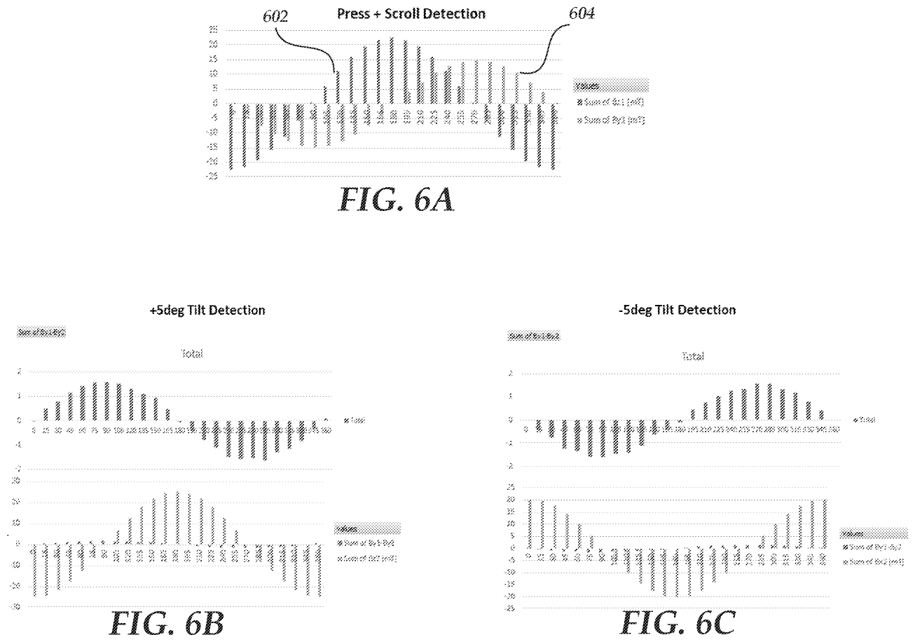

FIGS. 6A-6C illustrate example waveforms that can be generated by using different algorithms (e.g., summation or subtraction of outputs along a single x, y or z axis) to process outputs of Hall effect sensors (e.g., Hall effect sensors 214) under different manipulations of a scroll wheel (e.g., scroll wheel 108) by a user. FIG. 6A illustrates the waveform associated with the sensing performed by the Hall effect sensors 214 when the user presses and scrolls the scroll wheel 108. FIG. 6B illustrates the waveform associated with the sensing performed by the Hall effect sensors 214 when the user tilts the scroll wheel 108 by +5 degrees (e.g., tilt the scroll wheel 108 to the left). FIG. 6C illustrates the waveform associated with the sensing performed by the Hall effect sensors 214 when the user tilts the scroll wheel 108 by −5 degrees (e.g., tilt the scroll wheel 108 to the right). FIGS. 6A-6C illustrate that the outputs generated by the Hall effect sensors 214 of the steering wheel switch 200 can be processed to sense user manipulations of the scroll wheel 108 across all possible scroll wheel movement angles.

For example, as shown in FIG. 6A, the y-axis represents the magnitude of the sensed magnetic flux (e.g., in the unit of tesla) and the x-axis represents the degree (e.g., from 0 to 360 degrees) that the scroll wheel 108 may be pressed and scrolled. In FIG. 6A, waveform 602 results from adopting an algorithm that sums the outputs generated by the Hall effect sensors 214 along the z-axis while waveform 604 results from adopting also the algorithm that sums the outputs generated by the Hall effect sensors 214 along the y-axis. Waveform 602 shows almost 0 magnetic flux detected at 90 degrees and 270 degrees of scrolling while waveform 604 shows almost 0 magnetic flux detected at 180 degrees and 360 degrees of scrolling. As such, the almost 0 magnetic flux at 90 degrees and 270 degrees for waveform 602 can be compensated by waveform 604 and the almost 0 magnetic flux at 180 degrees and 360 degrees for waveform 604 can be compensated by waveform 602, thereby achieving press and scroll sensing across 0 to 360 degrees.

In some embodiments, the number of 3D Hall effect sensors utilized to generate the waveforms illustrated in FIGS. 6A-6C can vary and may be less than or more than two. For example, the steering wheel switch 100 may employ one 3D Hall effect sensor 214 to sense the press, tilt to the left and tilt to the right operations on the scroll wheel 108 by a user. In some embodiments, in addition to using one or more 3D Hall effect sensors for sensing pressing and tilting operations by the user on the scroll wheel 108, the steering wheel switch 100 may further employ mechanical microswitches to sense the pressing and tilting operations by the user. For example, three microswitches may be deployed within the steering wheel switch 100 where one senses user scrolling and pressing, another senses user tilting to the left, and the other senses user tilting to the right. As discussed above, such approach provides system redundancy for validating sensing functions performed by both the 3D Hall effect sensors and the microswitches, thereby increasing the reliability of the sensing and haptic feedback provided by the steering wheel switch 100.

In some embodiments, a calibration process 700 can be performed on the steering wheel switch 100. The calibration process 700 can improve on the ability of the switchpack to distinguish between types of user manipulations. Exemplary types of user manipulations include pressing vs. scrolling of the steering wheel switch 100. In certain embodiments, the calibration process 700 can reduce the likelihood that the switchpack will falsely detect the user scrolling the steering wheel switch 100 as instead pressing the steering wheel switch 100 and vice versa. Advantageously, after the calibration process 700 is performed, the steering wheel switch 100 can better distinguish various types of motion (e.g., scrolling and pressing) associated with the scroll wheel 108 at various angular positions (e.g., from 0 to 360 degrees).

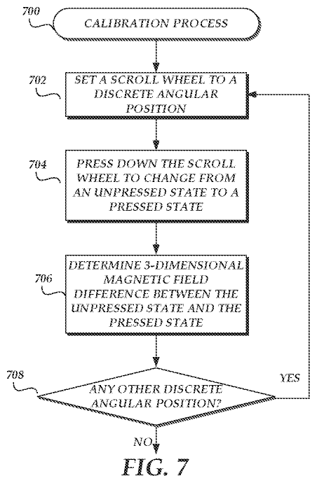

FIG. 7 illustrates the calibration process 700 for calibrating a scroll wheel of a steering wheel switch, such as the scroll wheel 108 of the steering wheel switch 100 of FIG. 1, in accordance with some embodiments of the present disclosure. The calibration process 700 begins at block 702, where a rotational alignment of the scroll wheel 108 may be fixed or set to a discrete angular position (e.g., a degree between 0 degrees to 360 degrees).

At block 704, the scroll wheel 108 may be pressed down to change the scroll wheel 108 from an unpressed state to a pressed state.

At block 706, a 3D magnetic field difference between the unpressed state and the pressed state may be determined. For example, magnitudes of magnetic flux along x-axis, y-axis, and z-axis sensed by the 3D Hall effect sensor 214 can be measured both before the scroll wheel 108 is pressed down and after the scroll wheel 108 is pressed down. As such, differences between the measure values of the 3D magnetic field between the unpressed state and the pressed state may be determined.

The calibration process 700 then varies according to whether there are any other discrete angular positions with which the 3D magnetic field difference or change has not been determined at block 708. In the instance that there are other discrete angular positions with which the 3D magnetic field difference has not been determined, the calibration process 700 returns to block 702. At block 702 the scroll wheel 108 can be set or aligned to the next discrete angular position. If there are no more discrete angular positions at which the 3D magnetic field is to be measured, the calibration process 700 may end. Advantageously, the determined 3D magnetic field change between the pressed and the unpressed state associated with the scroll wheel 108 at one or more discrete angular positions can be utilized to reduce the likelihood that the switchpack will falsely detect the user scrolling the steering wheel switch 100 when the user is actually pressing the steering wheel switch 100 and vice versa.

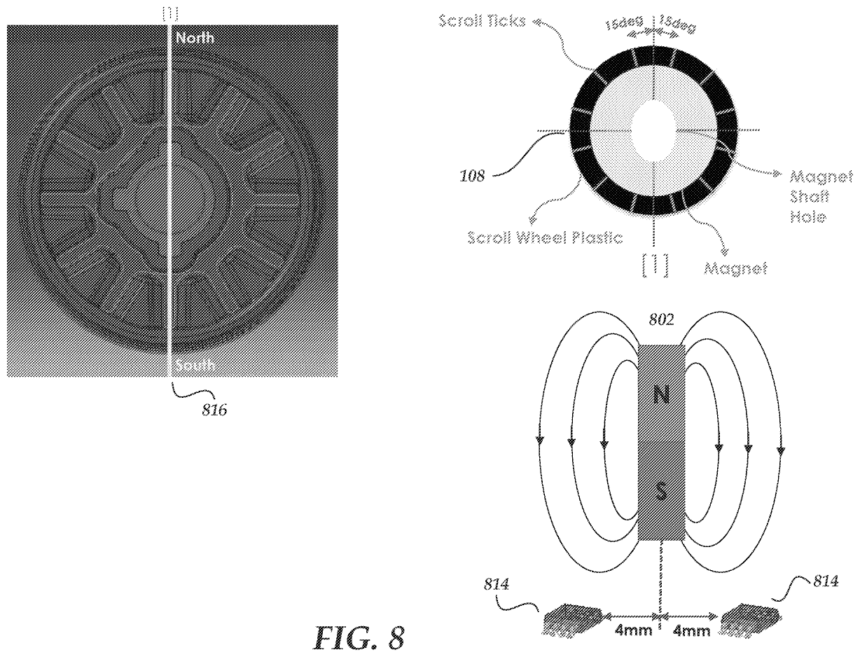

FIG. 8 illustrates an example integration of a magnet 802, the scroll wheel 108 and two 3D Hall effect sensors 814 that may be the same or similar to the 3D Hall effect sensors 214. As shown in FIG. 8, the magnet 802 may be enclosed within the scroll wheel 108, which includes a scroll wheel plastic and scroll ticks disposed on the scroll wheel plastic. Additionally, two 3D Hall effect sensors 814 are placed in such a way that each 3D Hall effect sensor 814 is at a distance that is 4 mm apart from the center of the magnet 802. In some embodiments, a 15-degree offset is arranged between the scroll ticks and the magnetization line 816 (e.g., the line extending from the North to the South of the magnet). Such arrangement can ensure that none of the scroll ticks aligns with the magnet boundary lines as magnetic field along the magnetic boundary line is at its minimum and may be harder to detect by the two 3D Hall effect sensors 814. As such, the 15-degree offset can result in better detection of the magnetic field by the two 3D Hall effect sensors 814. In other embodiments, other offset degrees other than 15 degrees can be employed.

Although two Hall effect sensors 814 are illustrated in FIG. 8, in some embodiments, there can be one or more than two Hall effect sensors 814 employed to sense the scroll, tilt or other operations by the user on the scroll wheel. In some embodiments, the distance between a 3D Hall effect sensor 814 and the center of the magnet can be less or more than 4 mm.

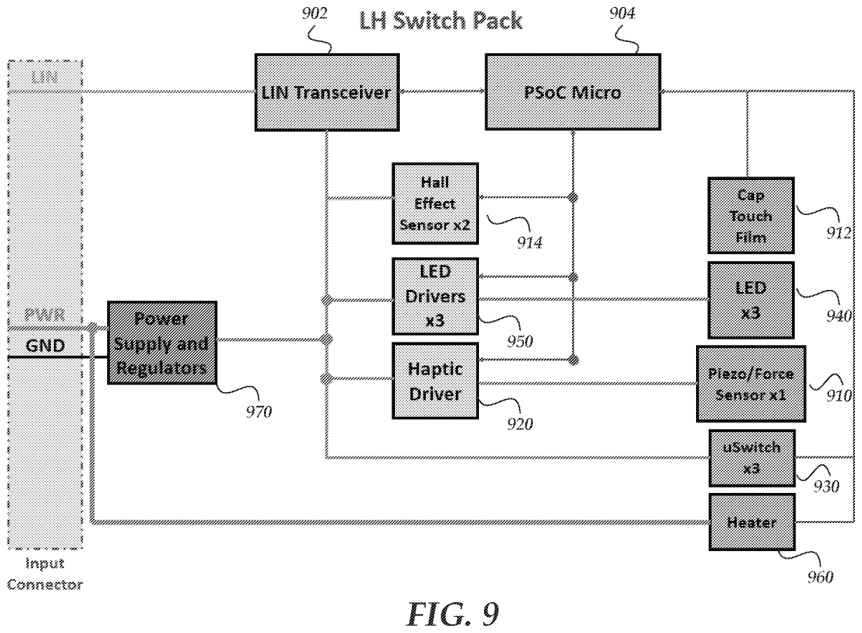

FIG. 9 illustrates an example block diagram showing different components that can be packed within a steering wheel switch, such as the steering wheel switch 100 of FIG. 1. As shown in FIG. 9, the steering wheel switch include a local interconnect network (LIN) transceiver 902, a Programmable System-on-Chip (PSoC) Microcontroller 904, two Hall effect sensors 914, a capacitive touch film 912, a piezoelectric sensor 910, a haptic driver 920, three microswitches 930, three light emitting diodes (LED) 940, three LED drivers 950, a heater 960 and a power supply and regulator 970.

In some embodiments, the piezoelectric sensor 910 can be the piezoelectric actuator 210 or 310; the Hall effect sensors 914 can be the Hall effect sensors 214; the capacitive touch film 912 can be the capacitive foil 212. As discussed above, the piezoelectric sensor 910 and the capacitive touch film 912 may each sense contact by a user and provide redundancy to validate the sensing functions performed to increase functional reliability. Redundancy is also obtained to increase reliability by using the two Hall effect sensors 914 and the three microswitches 930 to sense events such as press, scroll, tilt to different sides or directions on a scroll wheel (not shown in FIG. 9). Notably, the steering wheel switch shown in FIG. 9 can realize both force sensing and haptic feedback functionalities by using the piezoelectric sensor. Advantageously, using the piezoelectric sensor 910 can result in cost reduction and facilitate easier system integration.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed steering wheel switch.

It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural. Further, various embodiments disclosed herein are to be taken in the illustrative and explanatory sense, and should in no way be construed as limiting of the present disclosure.

All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other. Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

The illustrative algorithms described in connection with the embodiments disclosed herein can be implemented as electronic hardware (e.g., ASICs or FPGA devices), computer software that runs on computer hardware, or combinations of both. Moreover, the various illustrative logical blocks and modules described in connection with the embodiments disclosed herein can be implemented or performed by a machine, such as a processor device, a digital signal processor (“DSP”), an application specific integrated circuit (“ASIC”), a field programmable gate array (“FPGA”) or other programmable logic device, discrete gate or transistor logic, discrete hardware components, or any combination thereof designed to perform the functions described herein. A processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the rendering techniques described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

It will also be appreciated that one or more of the elements depicted in the drawings/figures can also be implemented in a more separated or integrated manner, or even removed or rendered as inoperable in certain cases, as is useful in accordance with a particular application.

1. A switchpack for a vehicle, comprising:
a piezoelectric actuator configured to:
generate a first electric signal in response to a first user contact associated with the switchpack; and
generate a haptic feedback based on a control signal; and
a processor configured to:
determine, based at least in part on the first electric signal, that the first user contact indicates a first user operation, and
generate the control signal based on the first user operation.

2. The switchpack of claim 1, further comprising:
a first button; and
a capacitive foil configured to generate a second electric signal in response to the first user contact,
wherein the processor determines that the first user contact indicates the first user operation further based on the second electric signal.

3. The switchpack of claim 2, wherein the first user operation is a user pressing the first button, or the user touching the first button without pressing the first button.

4. The switchpack of claim 2, further comprising:
a second button,
wherein a first ratio between a first distance from a center of the first button to a center of the piezoelectric actuator and a second distance from the center of the piezoelectric actuator to an edge of the switchpack equals a second ratio between a third distance from a center of the second button to the center of the piezoelectric actuator and a fourth distance from the center of the piezoelectric actuator to the edge of the switchpack.

5. The switchpack of claim 1, further comprising:
a scroll wheel; and
a first 3D Hall effect sensor configured to generate a first sensing signal in response to a second user contact on the scroll wheel,
wherein the processor is further configured to determine, based at least in part on the first sensing signal, that the second user contact indicates a second user operation.

6. The switchpack of claim 5, wherein the second user operation is a press on the scroll wheel, a tilt to a right on the scroll wheel, or a tilt to a left on the scroll wheel.

7. The switchpack of claim 5, further comprising:
a mechanical microswitch configured to generate a second sensing signal in response to the second user contact,
wherein the processor determines that the second user contact indicates the second user operation further based on the second sensing signal.

8. The switchpack of claim 5, further comprising:
a second 3D Hall effect sensor configured to generate a third sensing signal in response to the second user contact,
wherein the processor determines that the second user contact indicates the second user operation further based on the third sensing signal.

9. The switchpack of claim 8, wherein determining that the second user contact indicates the second user operation comprises: summing the first sensing signal and the third sensing signal along a x-axis; summing the first sensing signal and the third sensing signal along a y-axis; or summing the first sensing signal and the third sensing signal along a z-axis.

10. The switchpack of claim 8, further comprising:
a magnet at least partially surrounded by the scroll wheel,
wherein the first 3D Hall effect sensor and the second 3D Hall effect sensor are equally distant from a magnetization line of the magnet.

11. The switchpack of claim 10, wherein the scroll wheel comprises a first scroll tick and a second scroll tick, and wherein the first scroll tick and the second scroll tick have about a 15-degree offset against the magnetization line of the magnet.

12. A steering wheel for a vehicle, comprising:
a steering wheel switch, comprising:
a sensor configured to:
generate a first electric signal in response to a first user contact associated with the steering wheel switch; and
generate a haptic feedback based on a control signal; and
a processor configured to:
determine, based at least in part on the first electric signal, that the first user contact indicates a first user operation; and
generate the control signal based on the first user operation.

13. The steering wheel of claim 12, further comprising:
a button, and
a capacitive foil configured to generate a second electric signal in response to the first user contact,
wherein the processor determines that the first user contact indicates the first user operation further based on the second electric signal.

14. The steering wheel of claim 12, further comprising:
a scroll wheel; and
a first 3D Hall effect sensor configured to generate a first sensing signal in response to a second user contact on the scroll wheel,
wherein the processor is further configured to determine, based at least in part on the first sensing signal, that the second user contact indicates a second user operation.

15. The steering wheel of claim 14, further comprising:
a mechanical microswitch configured to generate a second sensing signal in response to the second user contact,
wherein the processor determines that the second user contact indicates the second user operation further based on the second sensing signal.

16. The steering wheel of claim 15, further comprising:
a second 3D Hall effect sensor configured to generate a third sensing signal in response to the second user contact,
wherein the processor determines that the second user contact indicates the second user operation further based on the third sensing signal.

17. A method for calibrating a steering wheel switch of a vehicle, the method comprising:
setting a scroll wheel to a first discrete angular position;
pressing the scroll wheel to change the scroll wheel from an unpressed state to a pressed state; and
determining a first 3D magnetic field difference associated with the unpressed state and the pressed state at the first discrete angular position.

18. The method of claim 17, further comprising:
sensing a first 3D magnetic field associated with the unpressed state at the first discrete angular position; and
sensing a second 3D magnetic field associated with the pressed state at the first discrete angular position,
wherein determining the first 3D magnetic field difference is based on the first 3D magnetic field and the second 3D magnetic field.

19. The method of claim 17, further comprising:
recording the first 3D magnetic field difference;
setting the scroll wheel to a second discrete angular position;
pressing the scroll wheel to change the scroll wheel from the unpressed state to the pressed state;
determining a second 3D magnetic field difference associated with the unpressed state and the pressed state at the second discrete angular position; and
recording the second 3D magnetic field difference.

20. The method of claim 17, further comprising:
generating a sensing signal in response to a first user contact on the scroll wheel; and
determining, based at least in part on the sensing signal and the first 3D magnetic field difference, that the first user contact indicates a first user operation,
wherein the first user operation is a press on the scroll wheel, a tilt to a right on the scroll wheel, or a tilt to a left on the scroll wheel.
